(19) United States
(12) Patent Application Publication
(10) Pub. No.: US 2013/0112256 A1
(43) Pub. Date: May 9, 2013

(54) VERTICAL PILLAR STRUCTURED PHOTOVOLTAIC DEVICES WITH WAVELENGTH-SELECTIVE MIRRORS

(71) Applicants: Young-June YU, Cranbury, NJ (US); Munib WOBER, Topsfield, MA (US)

(72) Inventors: Young-June YU, Cranbury, NJ (US); Munib WOBER, Topsfield, MA (US)

(21) Appl. No.: 13/288,131

(22) Filed: Nov. 3, 2011

(51) Int. Cl. H01L 31/0236; H01L 31/0376; H01L 31/0216; H01L 31/0352; H01L 31/10; H01L 31/18

(52) U.S. Cl. 136/256; 257/432; 438/70; 250/200; 257/184; 257/53; 257/E31.129; 257/E31.13; 257/E31.047; 257/E31.032; 257/E31.053; 257/E31.121

(57) ABSTRACT

A photovoltaic device operable to convert light to electricity, comprising a substrate, one or more structures essentially perpendicular to the substrate, and a wavelength-selective layer disposed on the substrate, wherein the structures comprise a crystalline semiconductor material.

### CROSS-REFERENCE TO RELATED APPLICATIONS

This application is related to U.S. Patent Application Ser. Nos. 61/266,064, 61/357,429, 61/360,421, 12/204,686 (granted as U.S. Pat. No. 7,646,943), 12/270,233, 12/472,264, 12/472,271, 12/478,598, 12/573,582, 12/575,221, 12/633,297, 12/633,305, 12/633,313, 12/633,318, 12/633,323, 12/621,497,12/648,942, 12/910,664, 12/945,492, 12/966,514, 12/966,535, 12/966,573, 12/967,880, 12/974,499, 12/982,269, 13/047,392, 13/048,635, 13/106,851, and 61/488,535, the disclosures of which are hereby incorporated by reference in their entirety.

### BACKGROUND OF THE INVENTION

A photovoltaic device, also called a solar cell is a solid state device that converts the energy of sunlight directly into electricity by the photovoltaic effect. Assemblies of cells are used to make solar modules, also known as solar panels. The energy generated from these solar modules, referred to as solar power, is an example of solar energy.

The photovoltaic effect is the creation of a voltage (or a corresponding electric current) in a material upon exposure to light. Though the photovoltaic effect is directly related to the photoelectric effect, the two processes are different and should be distinguished. In the photoelectric effect, electrons are ejected from a material's surface upon exposure to radiation of sufficient energy. The photovoltaic effect is different in that the generated electrons are transferred between different bands (i.e. from the valence to conduction bands) within the material, resulting in the buildup of a voltage between two electrodes.

Photovoltaics is a method for generating electric power by using solar cells to convert energy from the sun into electricity. The photovoltaic effect refers to photons of light-packets of solar energy-knocking electrons into a higher state of energy to create electricity. At higher state of energy, the electron is able to escape from its normal position associated with a single atom in the semiconductor to become part of the current in an electrical circuit. These photons contain different amounts of energy that correspond to the different wavelengths of the solar spectrum. When photons strike a PV cell, they may be reflected or absorbed, or they may pass right through. The absorbed photons can generate electricity. The term photovoltaic denotes the unbiased operating mode of a photodiode in which current through the device is entirely due to the light energy. Virtually all photovoltaic devices are some type of photodiode.

### BRIEF SUMMARY OF THE INVENTION

Described herein is a photovoltaic device operable to convert light to electricity, comprising a substrate, one or more structures essentially perpendicular to the substrate, and a wavelength-selective layer disposed on the substrate, wherein the structures comprise a crystalline semiconductor material.

### BRIEF DESCRIPTION OF THE DRAWINGS

FIG. 1A is a schematic cross sectional view of a photovoltaic device according to an embodiment.

FIG. 1B is a process of manufacturing the photovoltaic device of FIG. 1A, according to an embodiment.

FIG. 2A is a schematic cross sectional view of a photovoltaic device according to an embodiment.

FIG. 2B is a partial process of manufacturing the photovoltaic device of FIG. 2A, according to an embodiment.

FIG. 3 shows an exemplary top cross sectional view of the photovoltaic device.

FIG. 4 show a perspective view of a photovoltaic device according to an embodiment.

FIG. 5 shows alternative stripe-shaped structures of the photovoltaic device.

FIG. 6 shows alternative mesh-shaped structures of the photovoltaic device.

### DETAILED DESCRIPTION OF THE INVENTION

Described herein is a photovoltaic device operable to convert light to electricity, comprising a substrate, one or more structures essentially perpendicular to the substrate, and a wavelength-selective layer disposed on the substrate, preferably between the one or more structures, wherein the structures comprise a crystalline semiconductor material. The term “photovoltaic device” as used herein means a device that can generate electrical power by converting light such as solar radiation into electricity. Preferably, the crystalline semiconductor material is a single-crystal. The term “single-crystal” as used herein means that the crystal lattice of the material is continuous and unbroken throughout the entire structures, with essentially no grain boundaries therein. An electrically conductive material can be a material with essentially zero band gap. The electrical conductivity of an electrically conductive material is generally above 10³ S/cm. A semiconductor can be a material with a finite band gap up to about 3 eV and general has an electrical conductivity in the range of 10³ to 10⁻⁸ S/cm. An electrically insulating material can be a material with a band gap greater than about 3 eV and generally has an electrical conductivity below 10⁻⁸ S/cm. The term “structures essentially perpendicular to the substrate” as used herein means that angles between the structures and the substrate are from 85° to 90°.

According to an embodiment, the crystalline semiconductor material is selected from a group consisting of silicon, germanium, group III-V compound materials, group II-VI compound materials, and quaternary materials. A group III-V compound material as used herein means a compound consisting of a group III element and a group V element. A group III element can be B, Al, Ga, In, TI, Sc, Y, the lanthanide series of elements and the actinide series of elements. A group V element can be V, Nb, Ta, Db, N, P, As, Sb and Bi. A group II-VI compound material as used herein means a compound consisting of a group II element and a group VI element. A group II element can be Be, Mg, Ca, Sr, Ba and Ra. A group VI element can be Cr, Mo, W, Sg, O, S, Se, Te, and Po. A quaternary material is a compound consisting of four elements.

According to an embodiment, the structures are cylinders or prisms with a cross-section selected from a group consisting of elliptical, circular, rectangular, and polygonal cross-sections, strips, or a mesh. The term “mesh” as used herein means a web-like pattern or construction.

According to an embodiment, the structures are pillars with diameters from 50 nm to 20 μm, preferably 200 nm to 10 μm; heights from 1 μm to 100 μm, preferably 2 μm to 50 μm, a center-to-center distance between two closest pillars of preferably 300 nm to 15 μm.

According to an embodiment, each region between the structures can have a sidewall, a bottom wall, and a rounded, tapered or beveled inner edge between the sidewall and the bottom wall.

According to an embodiment, the wavelength-selective layer is operable to substantially transmit light of wavelengths above a threshold wavelength (e.g., with transmittance at least 30%, 40% or 50%) and substantially reflect light of wavelengths below the threshold wavelength (e.g., with reflectance at least 80%, 95% or 99%). For example, the threshold wavelength is a wavelength between 300 nm and 1100 nm, preferably between 500 nm and 700 nm, more preferably between 495 nm and 570 nm. The wavelength-selective layer can comprise a material selected from a group consisting of ZnO, Al, Au, Ag, Pd, Cr, Cu, Ti, and a combination thereof. The wavelength-selective layer is electrically conductive. The wavelength-selective layer preferably has a thickness of 15 nm to 30 nm. The wavelength-selective layers on the substrate are preferably connected. The wavelength-selective layer is preferably configured to substantially reflect light of wavelengths below the threshold wavelength incident on the wavelength-selective layer to the structures so that the light is absorbed by the structures. The wavelength-selective layer is preferably configured as an electrode of the photovoltaic device. The term “electrode” as used herein means a conductor used to establish electrical contact with the photovoltaic device. In an embodiment, the wavelength-selective layer comprises a dichroic mirror and an electrically conductive layer. In an embodiment, the wavelength-selective layer comprises an alternating stack dielectric and electrically conducting layers. The term “wavelength-selective layer” is used herein interchangeably with the term “wavelength-selective mirror.” A “dichroic mirror”, as used herein, comprises alternating layers of at least two materials with different refractive indexes. The interfaces between the alternating layers produce phased reflections, selectively reinforcing certain wavelengths of light and interfering with other wavelengths. The alternating layers can be deposited on a glass substrate by vacuum deposition. The dichroic mirror substantially transmits light of a wavelength in a range of wavelengths (a “passband”) and substantially reflects light of a wavelength outside the passband. By controlling the thickness and number of the alternating layers, the passband can be tuned and made as wide or narrow as desired.

According to an embodiment, the substrate has a flat surface opposite the structures. According to an embodiment, the flat surface has a doped layer, a metal layer disposed on and forming an Ohmic contact with the doped layer, and optionally a passivation layer disposed in some but not all areas between the doped layer and the metal layer. The metal layer is configured to reflect substantially all light with wavelengths above the threshold wavelength of the wavelength-selective layer. The passivation layer can be any suitable material such as an oxide. The passivation layer preferably has a thickness of 5 nm to 70 nm, more preferably about 20 nm. An Ohmic contact is a region a current-voltage (I-V) curve across which is linear and symmetric.

According to an embodiment, the substrate has a surface opposite the structures, the surface having recesses. According to an embodiment, the surface opposite the structures has a doped layer conformally coated thereon, a passivation layer disposed conformally on some but not all areas of the doped layer (e.g., on surfaces of the recesses but not on surfaces between the recesses), and a metal layer disposed conformally on the doped layer and the passivation layer and forming an Ohmic contact with the doped layer, preferably at least at areas without the passivation layer. The recesses can be filled and flattened with any suitable material.

According to an embodiment, the substrate has a thickness of 5 μm to 300 μm, preferably about 20 μm.

The term “cladding layer” as used herein means a layer of substance surrounding the structures. The term “continuous” as used herein means having no gaps, holes, or breaks. The term “coupling layer” as used herein means a layer effective to guide light into the structures.

According to an embodiment, the photovoltaic device further comprises a junction layer, a cladding layer and optionally a coupling layer, wherein: the junction layer is a doped semiconductor; the junction layer is disposed on the sidewall, on the bottom wall under the wavelength-selective layer, and on a top surface of the structures; the cladding layer is disposed over an entire exposed portion of the junction layer and the wavelength-selective layer; and/or the coupling layer is disposed on the cladding layer.

According to an embodiment further of the embodiment, the structures are a doped semiconductor and the structures and the junction layer have opposite conduction types.

According to an embodiment further of the embodiment, the junction layer has a thickness from 5 nm to 200 nm; the cladding layer is substantially transparent to visible light with a transmittance of at least 50%; the cladding layer is made of an electrically conductive material; the cladding layer is a transparent conductive oxide; the cladding layer is a material selected from a group consisting of indium tin oxide, aluminum doped zinc oxide, zinc indium oxide, and zinc tin oxide; the cladding layer has a thickness from 10 nm to 500 nm; the cladding layer forms an Ohmic contact with the wavelength-selective layer; the cladding layer is configured as an electrode of the photovoltaic device.

The coupling layer is the same material as the cladding layer or different material from the cladding layer; and/or a refractive index of the structures n1, a refractive index of the cladding layer n2, a refractive index of the coupling layer n3, satisfy relations of n1>n2>n3.

According to an embodiment, a method of making the photovoltaic device comprises: generating a pattern of openings in a resist layer using a lithography technique, wherein locations and shapes of the openings correspond to location and shapes of the structures; forming the structures and regions therebetween by etching the substrate; depositing the wavelength-selective layer to the bottom wall. A resist layer as used herein means a thin layer used to transfer a pattern to the substrate which the resist layer is deposited upon. A resist layer can be patterned via lithography to form a (sub)micrometer-scale, temporary mask that protects selected areas of the underlying substrate during subsequent processing steps. The resist is generally proprietary mixtures of a polymer or its precursor and other small molecules (e.g. photoacid generators) that have been specially formulated for a given lithography technology. Resists used during photolithography are called photoresists. Resists used during e-beam lithography are called e-beam resists. A lithography technique can be photolithography, e-beam lithography, holographic lithography. Photolithography is a process used in microfabrication to selectively remove parts of a thin film or the bulk of a substrate. It uses light to transfer a geometric pattern from a photo mask to a light-sensitive chemical photo resist, or simply “resist,” on the substrate. A series of chemical treatments then engraves the exposure pattern into the material underneath the photo resist. In complex integrated circuits, for example a modern CMOS, a wafer will go through the photolithographic cycle up to 50 times. E-beam lithography is the practice of scanning a beam of electrons in a patterned fashion across a surface covered with a film (called the resist), (“exposing” the resist) and of selectively removing either exposed or non-exposed regions of the resist (“developing”). The purpose, as with photolithography, is to create very small structures in the resist that can subsequently be transferred to the substrate material, often by etching. It was developed for manufacturing integrated circuits, and is also, used for creating nanotechnology artifacts.

According to an embodiment, the method of making the photovoltaic device further comprises ion implantation. Ion implantation is process by which ions of a material can be implanted into another solid, thereby changing the physical properties of the solid. Ion implantation is used in semiconductor device fabrication and in metal finishing, as well as various applications in materials science research. The ions introduce both a chemical change in the target, in that they can be a different element than the target or induce a nuclear transmutation, and a structural change, in that the crystal structure of the target can be damaged or even destroyed by the energetic collision cascades.

According to an embodiment, the structures and regions therebetween are formed by deep etch followed by isotropic etch. A deep etch is a highly anisotropic etch process used to create deep, steep-sided holes and trenches in wafers, with aspect ratios of often 20:1 or more. An exemplary deep etch is the Bosch process. The Bosch process, also known as pulsed or time-multiplexed etching, alternates repeatedly between two modes to achieve nearly vertical structures: 1. a standard, nearly isotropic plasma etch, wherein the plasma contains some ions, which attack the wafer from a nearly vertical direction (For silicon, this often uses sulfur hexafluoride (SF₆)); 2. deposition of a chemically inert passivation layer (for instance, C₄F₈ source gas yields a substance similar to Teflon). Each phase lasts for several seconds. The passivation layer protects the entire substrate from further chemical attack and prevents further etching. However, during the etching phase, the directional ions that bombard the substrate attack the passivation layer at the bottom of the trench (but not along the sides). They collide with it and sputter it off, exposing the substrate to the chemical etchant. These etch/deposit steps are repeated many times over resulting in a large number of very small isotropic etch steps taking place only at the bottom of the etched pits. To etch through a 0.5 mm silicon wafer, for example, 100-1000 etch/deposit steps are needed. The two-phase process causes the sidewalls to undulate with an amplitude of about 100-500 nm. The cycle time can be adjusted: short cycles yield smoother walls, and long cycles yield a higher etch rate. Isotropic etch is non-directional removal of material from a substrate via a chemical process using an etchant substance. The etchant may be a corrosive liquid or a chemically active ionized gas, known as a plasma.

According to an embodiment, a method of converting light to electricity comprises: exposing the photovoltaic device to light; drawing an electrical current from the photovoltaic device. The electrical current can be drawn from the wavelength-selective layer.

According to an embodiment, a photo detector comprises the photovoltaic device, wherein the photo detector is configured to output an electrical signal when exposed to light.

According to an embodiment, a method of detecting light comprises exposing the photovoltaic device to light; measuring an electrical signal from the photovoltaic device. The electrical signal can be an electrical current, an electrical voltage, an electrical conductance and/or an electrical resistance. A bias voltage is applied to the structures in the photovoltaic device.

According to an embodiment, photovoltaic devices produce direct current electricity from sun light, which can be used to power equipment or to recharge a battery. A practical application of photovoltaics was to power orbiting satellites and other spacecraft, but today the majority of photovoltaic modules are used for grid connected power generation. In this case an inverter is required to convert the DC to AC. There is a smaller market for off-grid power for remote dwellings, boats, recreational vehicles, electric cars, roadside emergency telephones, remote sensing, and cathodic protection of pipelines. In most photovoltaic applications the radiation is sunlight and for this reason the devices are known as solar cells. In the case of a p-n junction solar cell, illumination of the material results in the creation of an electric current as excited electrons and the remaining holes are swept in different directions by the built-in electric field of the depletion region. Solar cells are often electrically connected and encapsulated as a module. Photovoltaic modules often have a sheet of glass on the front (sun up) side, allowing light to pass while protecting the semiconductor wafers from the elements (rain, hail, etc.). Solar cells are also usually connected in series in modules, creating an additive voltage. Connecting cells in parallel will yield a higher current. Modules are then interconnected, in series or parallel, or both, to create an array with the desired peak DC voltage and current.

According to an embodiment, the photovoltaic device can also be associated with buildings: either integrated into them, mounted on them or mounted nearby on the ground. The photovoltaic device can be retrofitted into existing buildings, usually mounted on top of the existing roof structure or on the existing walls. Alternatively, the photovoltaic device can be located separately from the building but connected by cable to supply power for the building. The photovoltaic device can be used as as a principal or ancillary source of electrical power. The photovoltaic device can be incorporated into the roof or walls of a building.

According to an embodiment, the photovoltaic device can also be used for space applications such as in satellites, spacecrafts, space stations, etc. The photovoltaic device can be used as main or auxiliary power sources for land vehicles, marine vehicles (boats) and trains. Other applications include road signs, surveillance cameras, parking meters, personal mobile electronics (e.g., cell phones, smart phones, laptop computers, personal media players).

### EXAMPLES

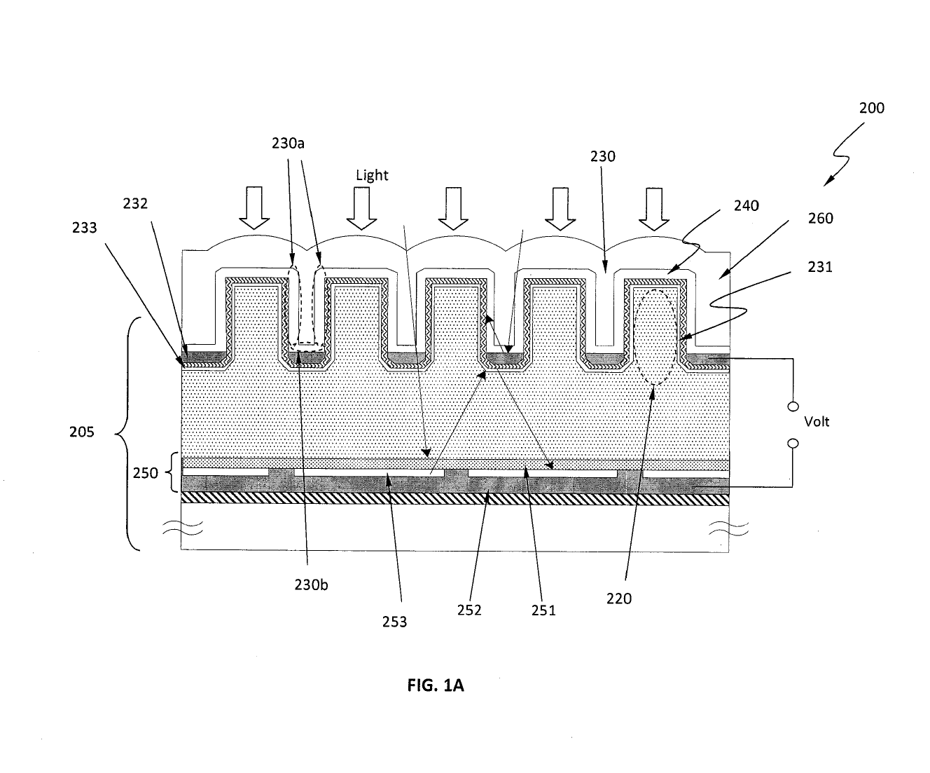

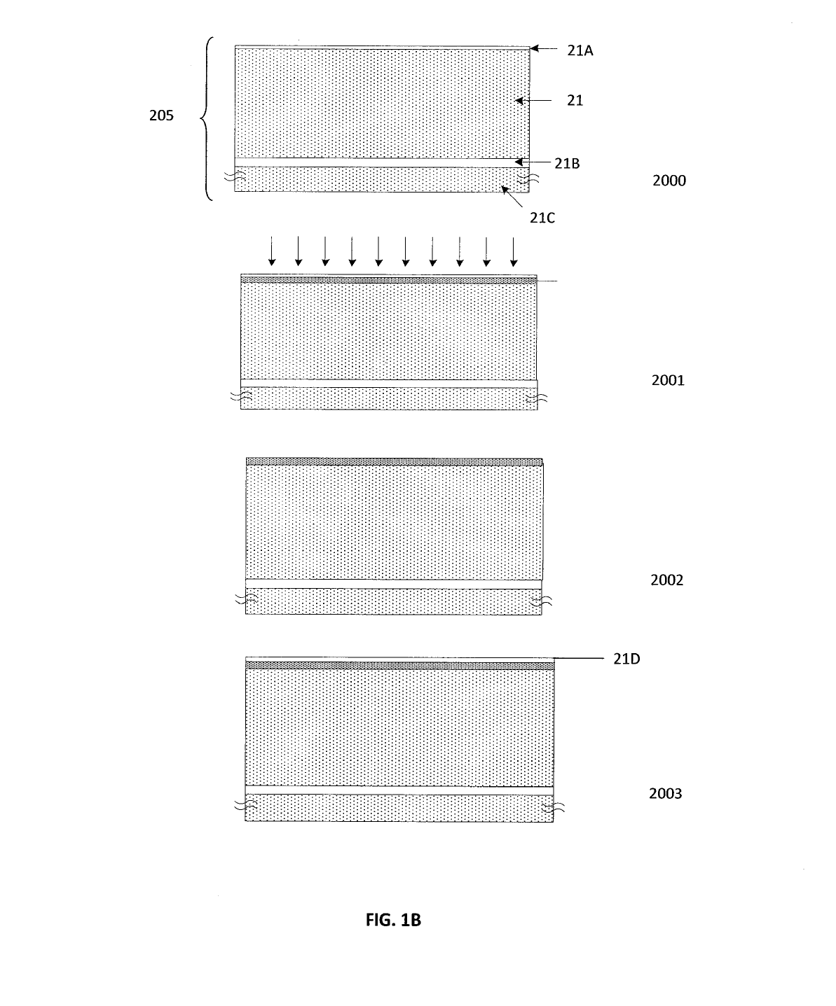

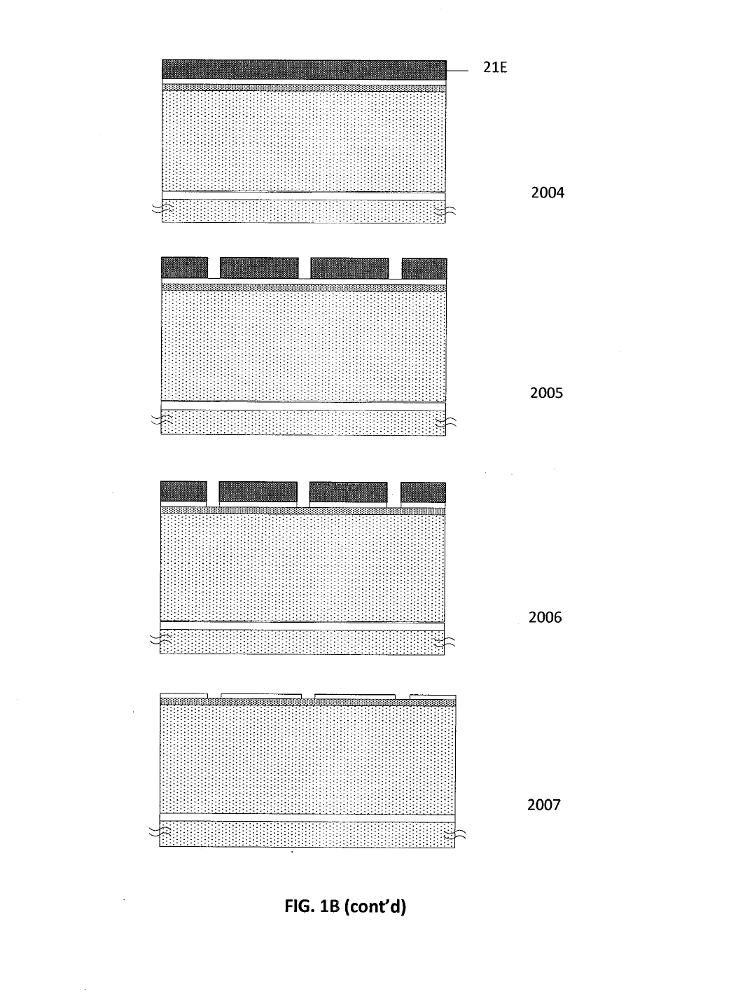

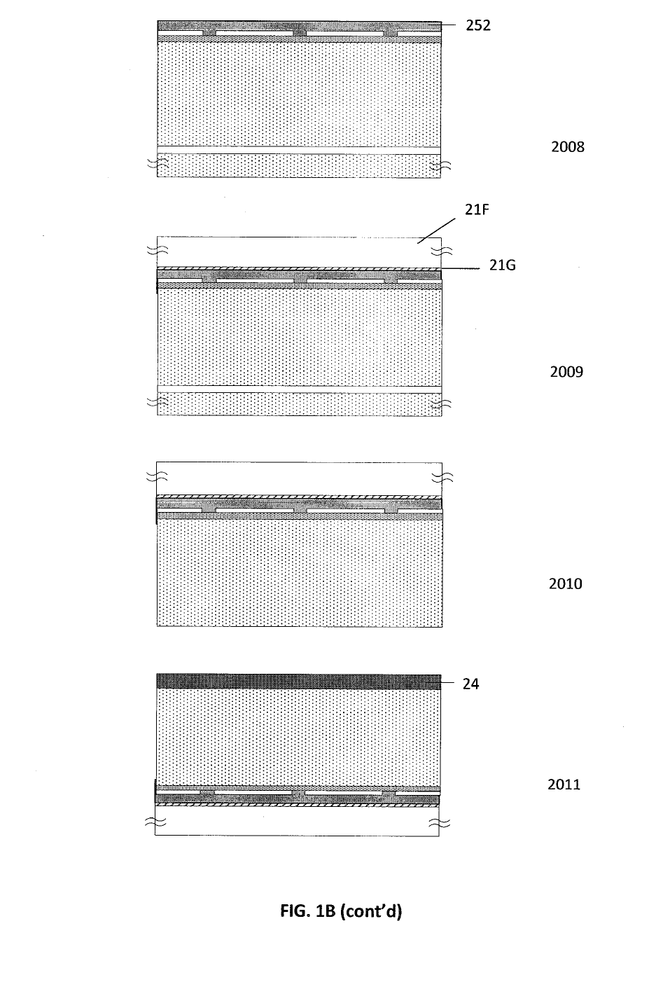

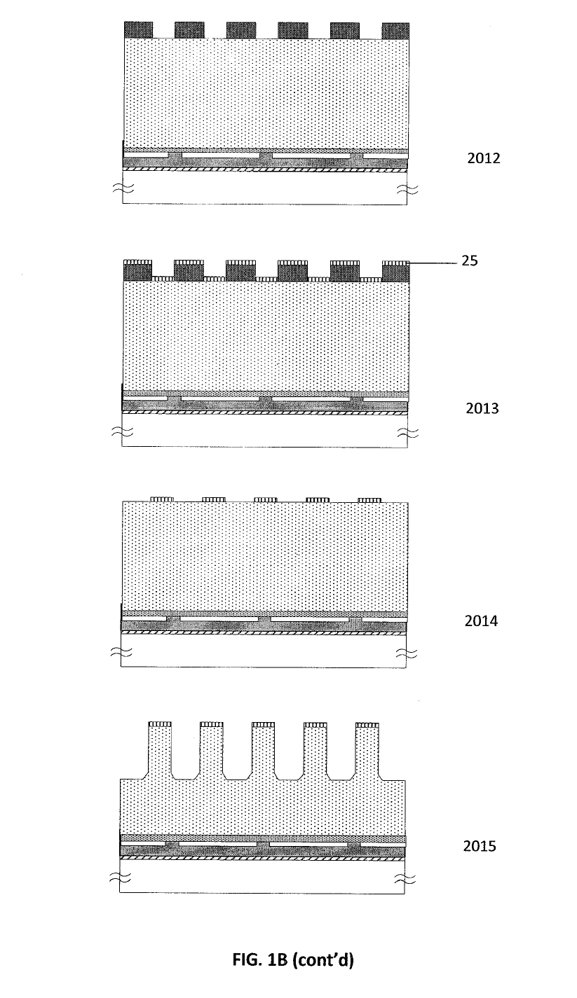

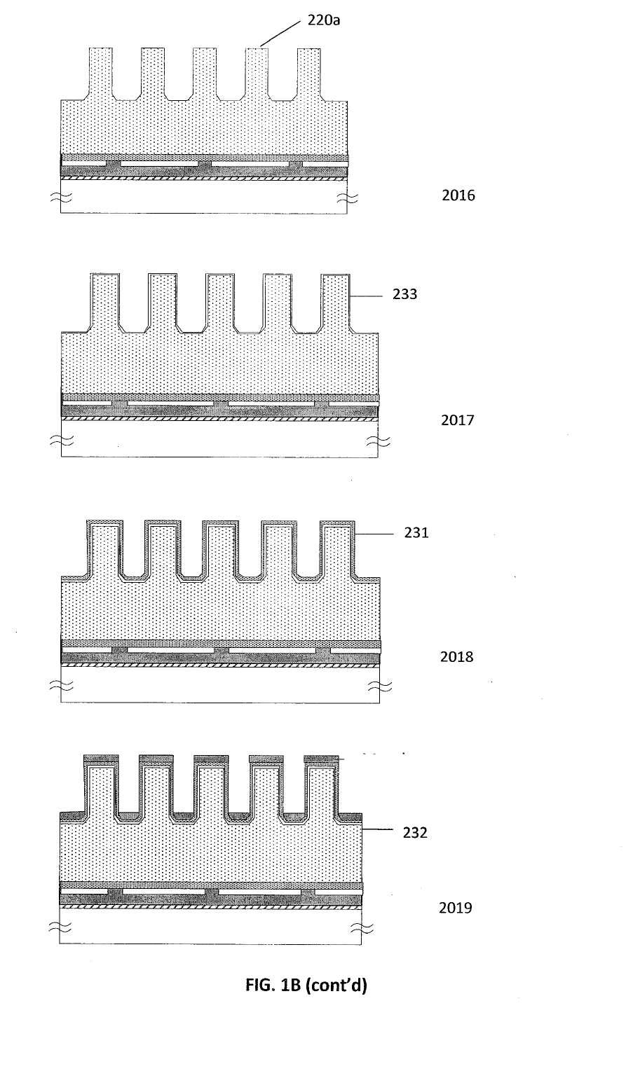

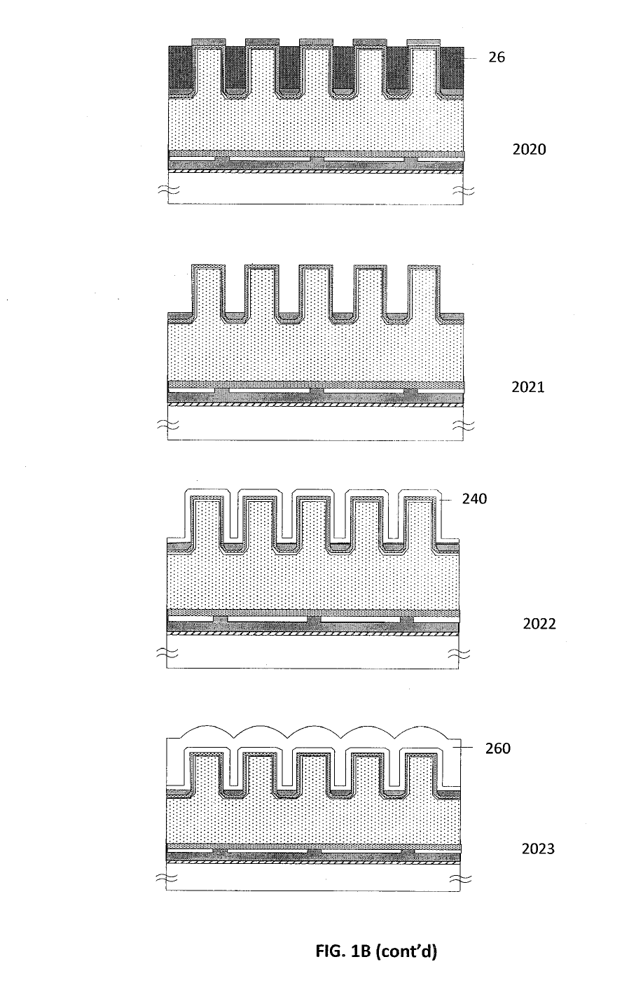

FIG. 1A shows a schematic cross-section of a photovoltaic device 200, according to an embodiment. The photovoltaic device 200 comprises a substrate 205, one or more structures 220 essentially perpendicular to the substrate 205. Each region 230 between the structures 220 has a sidewall 230a and a bottom wall 230b. The sidewall 230a, the bottom wall 230b of each region 230 and a top surface 220a of the structures 220 have a junction layer 231 disposed thereon. The junction layer 231 is a doped semiconductor having a bandgap higher than the bandgap of the structures 220. For example, when the structures 220 is a crystalline silicon substrate, the junction layer 231 is a doped amorphous silicon layer. Optionally, an intrinsic layer 233 may be deposited between the junction layer 231 and the structure 220. The intrinsic layer 233 is an intrinsic semiconductor, such as intrinsic amorphous silicon. The sidewall 230a preferably does not have any wavelength-selective layer. The structures 220 are a doped crystalline semiconductor material. The structures 220 and the junction layer 231 have opposite conduction types, i.e., if the structures 220 are p type, the junction layer 231 is n type; if the structures 220 are n type, the junction layer 231 is p type. The junction layer 231 and the structures 220 form a p-n junction in absence of the intrinsic layer 233; the junction layer 231, the intrinsic layer 233 and the structures 220 form a p-i-n junction if the intrinsic layer 233 is present. The bottom wall 230b has a wavelength-selective layer 232 disposed on the junction layer 231. A cladding layer 240 is disposed over an entire exposed junction layer 231, the wavelength-selective layer 232 and the top surface 220a. The photovoltaic device 200 can further comprise a coupling layer 260 disposed on the cladding layer 240. An intrinsic semiconductor, also called an undoped semiconductor or i-type semiconductor, is a substantially pure semiconductor without any significant dopant species present. The number of charge carriers is therefore determined by the properties of the material itself instead of the amount of impurities. In intrinsic semiconductors the number of excited electrons and the number of holes are substantially equal. External electric field is not substantially screened in an intrinsic semiconductor because the intrinsic semiconductor does not have mobile electrons or holes supplied by dopants. It is thus more efficient to remove and/or collect electrons and/or holes generated in an intrinsic semiconductor by photons.

The structures 220 can comprise any suitable crystalline semiconductor material, such as silicon, germanium, group III-V compound materials (e.g., gallium arsenide, gallium nitride, etc.), group II-VI compound materials (e.g., cadmium selenide, cadmium sulfide, cadmium telluride, zinc oxide, zinc selenide, etc.), quaternary materials (e.g., copper indium gallium selenide).

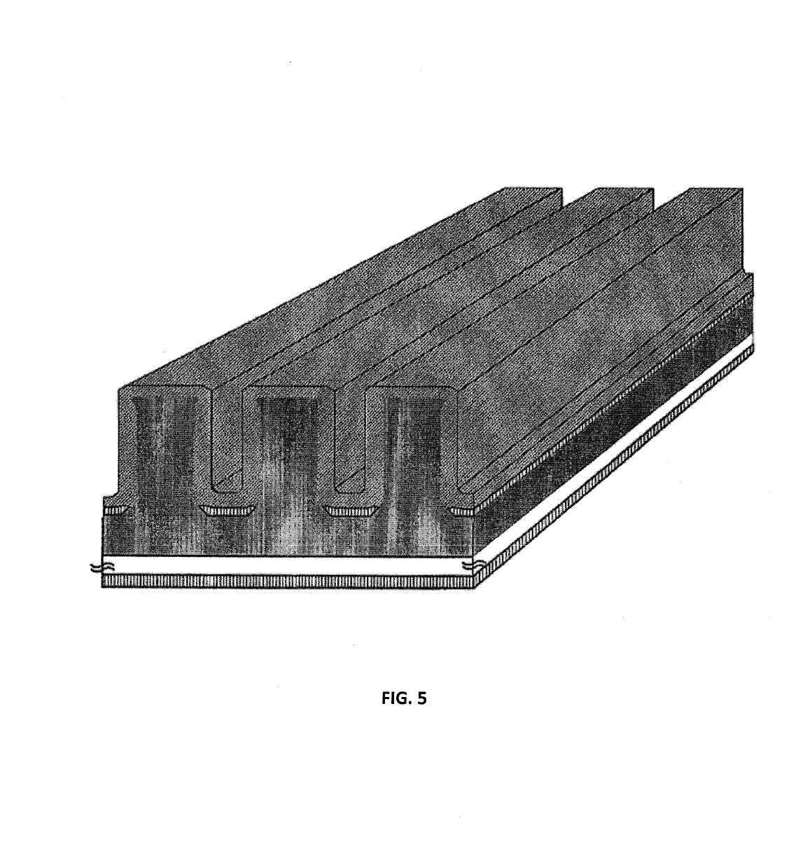

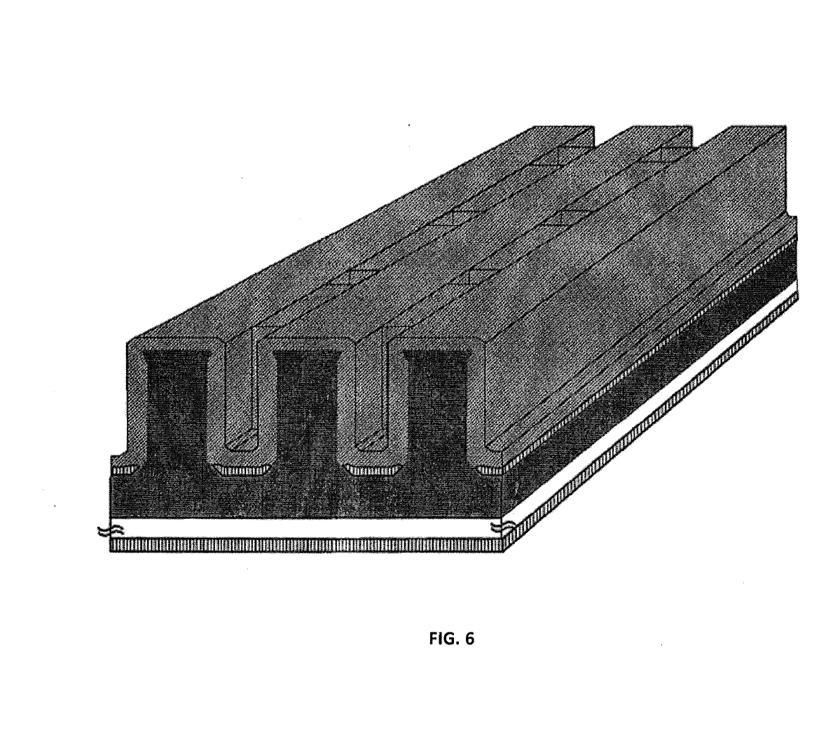

The structures 220 can have any cross-sectional shape. For example, the structures 220 can be cylinders or prisms with elliptical, circular, rectangular, polygonal cross-sections. The structures 220 can also be strips as shown in FIG. 5, or a mesh as shown in FIG. 6. According to one embodiment, the structures 220 are pillars with diameters from 50 nm to 20 μm, preferably 200 nm to 10 μm; heights from 1 μm to 100 μm, preferably 2 μto 50 μm, a center-to-center distance between two closest pillars of preferably 300 nm to 15 μm.

Each region 230 preferably has a rounded, tapered or beveled inner edge between the sidewall 230a and the bottom wall 230b.

The junction layer 231 preferably has a thickness from 5 nm to 200 nm. The junction layer 231 or the intrinsic layer 233 is effective to passivate surfaces of the structures 220.

The cladding layer 240 is substantially transparent to visible light, preferably with a transmittance of at least 50%, more preferably at least 70%, most preferably at least 90%. The cladding layer 240 preferably is made of an electrically conductive material. The cladding layer 240 preferably is made of a transparent conductive oxide, such as ITO (indium tin oxide), AZO (aluminum doped zinc oxide), ZIO (zinc indium oxide), ZTO (zinc tin oxide), etc. The cladding layer 240 can have a thickness of 10 nm to 500 nm. The cladding layer 240 preferably forms an Ohmic contact with the junction layer 231. The cladding layer 240 preferably forms an Ohmic contact with the wavelength-selective layer 232. The cladding layer 240 preferably is configured as an electrode of the photovoltaic device 200.

The substrate 205 preferably has a flat surface 250 opposite the structures 220. The flat surface 250 can have a doped layer 251 of the same conduction type from the structures 220, i.e. if the structure 220s are p type, the doped layer 251 is p type; if the structures 220 are n type, the doped layer 251 is n type. Preferably, the doped layer 251 has higher doping level than the structures 220. The doped layer 251 is electrically connected to each of the structures 220. The flat surface 250 can also have a passivation layer 253 deposited on the doped layer 251. The passivation layer 253 can be configured to passivate surface of the doped layer 251, which can reduce dark current and carrier recombination at the surface of the doped layer 251. The passivation layer 253 can comprise oxide. The passivation layer 253 has a plurality of openings wherein the doped layer 251 is exposed. The flat surface 250 can also have a metal layer 252 disposed on the passivation layer 253. The metal layer 252 forms an Ohmic contact with the doped layer 251 at the plurality of openings of the passivation layer 253. The metal layer 252 is configured to reflect essentially all light passing through the substrate 205 back towards the structures 220. The substrate 205 preferably has a thickness of 5 μm to 300 μm and more preferably about 20 μm. Total area of the wavelength-selective layer 232 is preferable at least 40% of a surface area of the flat surface 250.

The coupling layer 260 can be of the same material as the cladding layer 240 or different material from the cladding layer 240. Refractive index of the structure 220 n1, refractive index of the cladding layer 240 n2, refractive index of the coupling layer 260 n3, preferably satisfy relations of n1>n2>n3, which lead to enhanced light concentration in the structures 220.

In one embodiment, the structures 220 are pillars arranged in an array, such as a rectangular array, a hexagonal array, a square array, concentric ring.

A method of making the photovoltaic device 200 as shown in FIG. 1B, according to an embodiment, comprises the following steps:

In step 2000, the substrate 205 is provided, which is a silicon-on-insulator (SOI) substrate having a doped silicon layer 21 capped by an oxide layer 21A, a buried oxide layer 21B and a support layer 21C.

In step 2001, the doped layer 251 is formed by further doping a layer of the doped silicon layer 21 immediately under the oxide layer 21A by ion implantation.

In step 2002, the oxide layer 21A is removed by a suitable method such as wet etch.

In step 2003, an oxide layer 21D is deposited onto the doped layer 251 by a suitable method such as plasma-enhanced chemical vapor deposition (PECVD) or dry oxidation. The oxide layer 21D can have a thickness of about 20 nm.

In step 2004, a resist layer 21E is applied to the oxide layer 21D. The resist layer 21E can be applied by spin coating. The resist layer 21E can be a photo resist or an e-beam resist.

In step 2005, lithography is performed. The resist layer 21E now has a pattern of openings in which the oxide layer 21D is exposed. The resolution of the lithography is limited by the wavelength of the radiation used. Photolithography tools using deep ultraviolet (DUV) light with wavelengths of approximately 248 and 193 nm, allows minimum feature sizes down to about 50 nm. E-beam lithography tools using electron energy of 1 keV to 50 keV allows minimum feature sizes down to a few nanometers.

In step 2006, exposed portions of the oxide 21D is removed by a suitable method such as dry etch or wet etch. Now the doped layer 251 is exposed in the openings of the resist layer 21E.

In step 2007, remainder of the resist layer 21E is lift off by a suitable solvent or ashed in a resist asher.

In step 2008, the metal layer 252 is deposited by a suitable method such as evaporation or sputtering. The metal layer 252 can comprise Al, Cu, Ti, Cr, Ag, Au, Pt, or a combination thereof. The metal layer 252 contacts the doped layer 251.

In step 2009, a wafer 21F is attached to the metal layer 252 to provide mechanical. support. The wafer 21F can be attached by a heat conductive glue 21G. The wafer 21F can be any suitable wafer such as a ceramic plate, metal plate, glass plate, carbon fiber reinforced polymer (CFRP).

In step 2010, the support layer 21C and the buried oxide layer 21B are removed by a suitable method such as wet etch. To protect features on the doped silicon layer 21, wax can be deposited on the wafer 21F and sidewalls of the substrate 205. The wax can be removed after the support layer 21C and the buried oxide layer 21B are removed.

In step 2011, a resist layer 24 is applied on the doped silicon layer 21. The resist layer 24 can be applied by spin coating. The resist layer 24 can be a photo resist or an e-beam resist.

In step 2012, lithography is performed. The resist layer 24 now has a pattern of openings in which the doped silicon layer 21 is exposed. Shapes and locations of the openings correspond to the shapes and locations of the regions 230.

In step 2013, a mask layer 25 is deposited. The deposition can be done using a technique such as thermal evaporation, e-beam evaporation, sputtering. The mask layer 25 can be a metal such as Cr or Al, or a dielectric such as SiO₂ or Si₃N₄. The thickness of the mask layer 25 can be determined by a depth of the regions 230 and etching selectivity (i.e., ratio of etching rates of the mask layer 25 and the substrate 205).

In step 2014, remainder of the resist layer 24 is lift off by a suitable solvent or ashed in a resist asher to remove any mask layer 25 support thereon. A portion of the mask layer 25 in the openings of the resist layer 24 is retained. A portion of the doped silicon layer 21 is now exposed through the retained mask layer 25.

In step 2015, the exposed portion of the doped silicon layer 21 is deep etched to a desired depth, to form the structures 220 and the regions 230 with the beveled inner edge. Deep etching includes alternating deposition and etch steps and can lead to “scalloping” on the sidewall 230b of the regions 230, i.e. the sidewall 230b is not smooth. The sidewall 230b can be smoothed by thermal annealing or dipping into an etchant such as potassium hydroxide (KOH) followed by rinsing. The deep etching can use gases such as C₄F₈ and SF₆.

In step 2016, the mask layer 25 is removed by a suitable such as wet etching with suitable etchant, ion milling, sputtering.

In step 2017, if the intrinsic layer 233 is desired, it is deposited conformally (i.e., isotropically) on surfaces of the regions 230 and a top surface 220a of the structures 220. The intrinsic layer 233 can be deposited by a suitable technique such as plating, chemical vapor deposition or atomic layer deposition. If the intrinsic layer 233 is not desired, step 2017 can be omitted.

In step 2018, the junction layer 231 is conformally (i.e., isotropically) deposited on the intrinsic layer 233 if step 2017 is carried or on the surfaces of the regions 230 and the top surface 220a of the structures 220 if step 2017 is omitted. The junction layer 231 can be deposited by a suitable technique such as plating, chemical vapor deposition or atomic layer deposition.

In step 2019, the wavelength-selective layer 232 is anisotropically deposited (i.e., non-conformally) such that the junction layer 231 on the top surface 220a and the bottom wall 230b are covered by the wavelength-selective layer 232 while the sidewall 230a is free of the wavelength-selective layer 232. The wavelength-selective layer 232 can be deposited by a suitable technique such as thermal evaporation, e-beam evaporation.

In step 2020, a resist layer 26 is deposited such that the regions 230 are filled and the wavelength-selective layer 232 on the top surface 220a is covered. The resist layer 26 is dry etched until the wavelength-selective layer 232 on the top surface 220a is exposed.

In step 2021, the wavelength-selective layer 232 on the top surface 220a is removed by a suitable method such as dry etch or wet etch. The resist layer 26 is lift off by a suitable solvent or ashed in a resist asher.

In step 2022, the cladding layer 240 is conformally (i.e., isotropically) deposited such that the wavelength-selective layer 232 and the junction layer 231 are completely covered. The cladding layer 240 can be deposited by a suitable technique such as sputter, plating, chemical vapor deposition or atomic layer deposition.

In step 2023, the coupling layer 260 is conformally (i.e., isotropically) deposited using a suitable technique such as sputtering, thermal evaporation or e-beam evaporation.

The method can further comprise one or more steps, of thermal annealing.

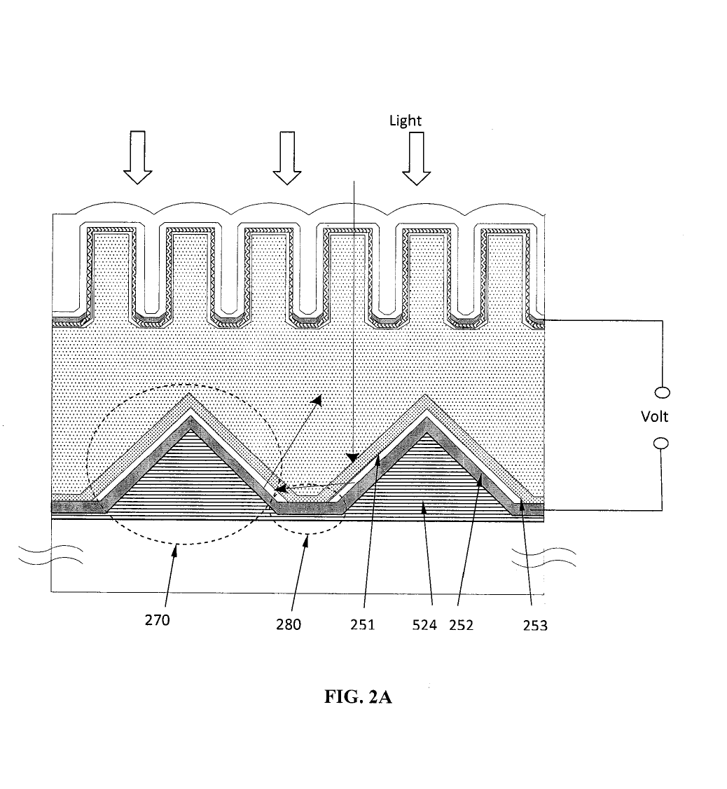

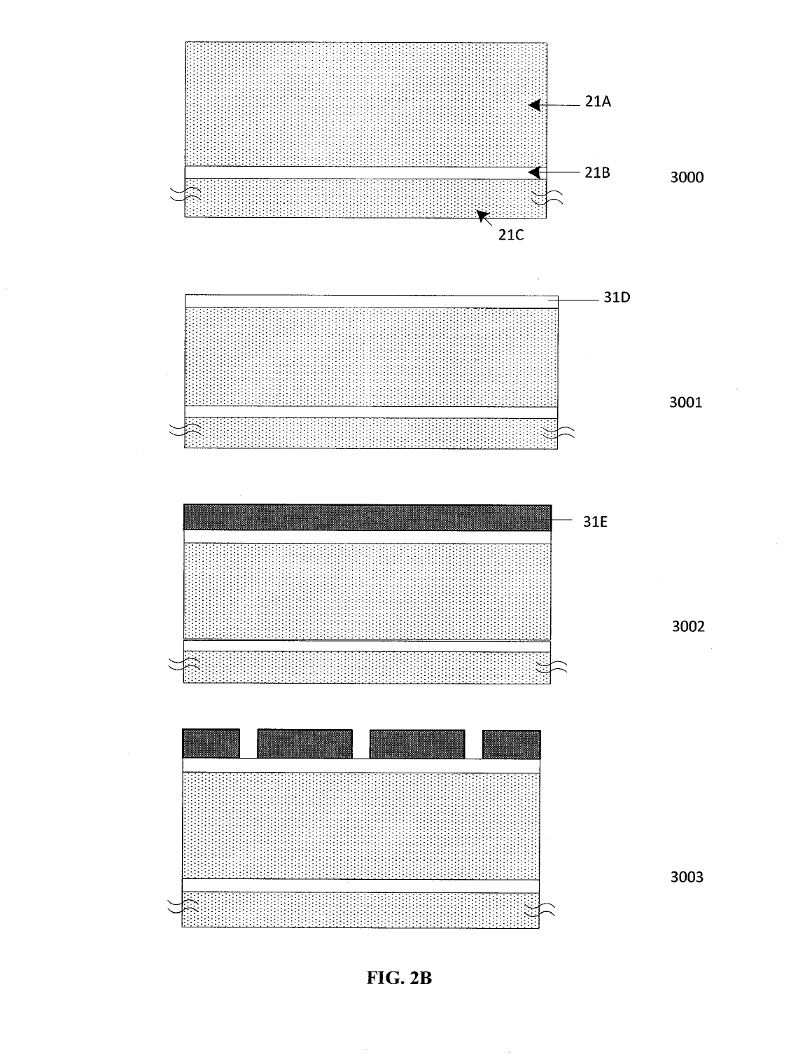

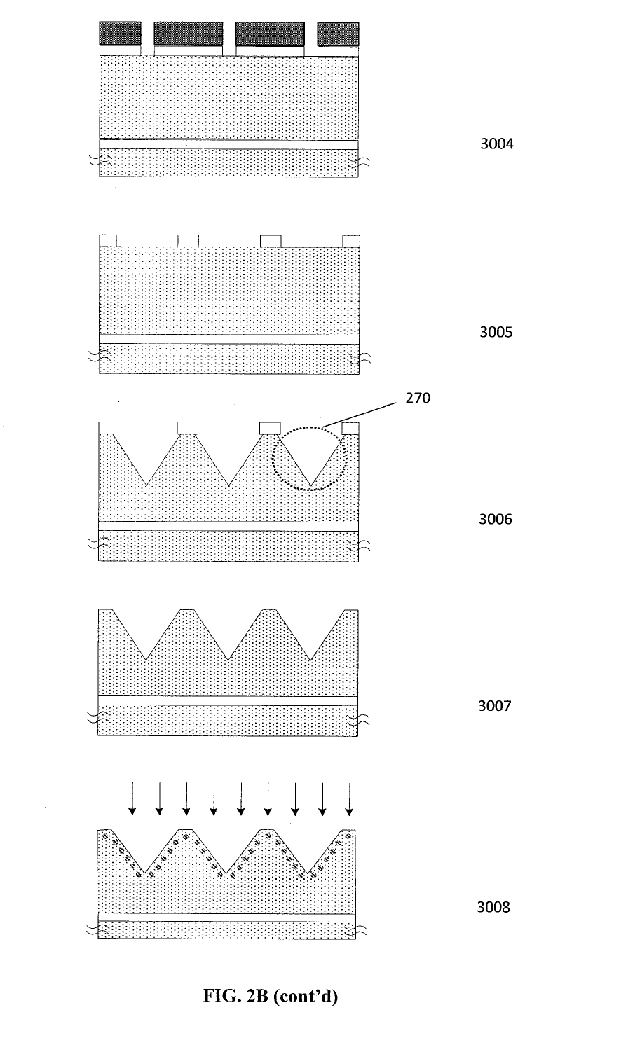

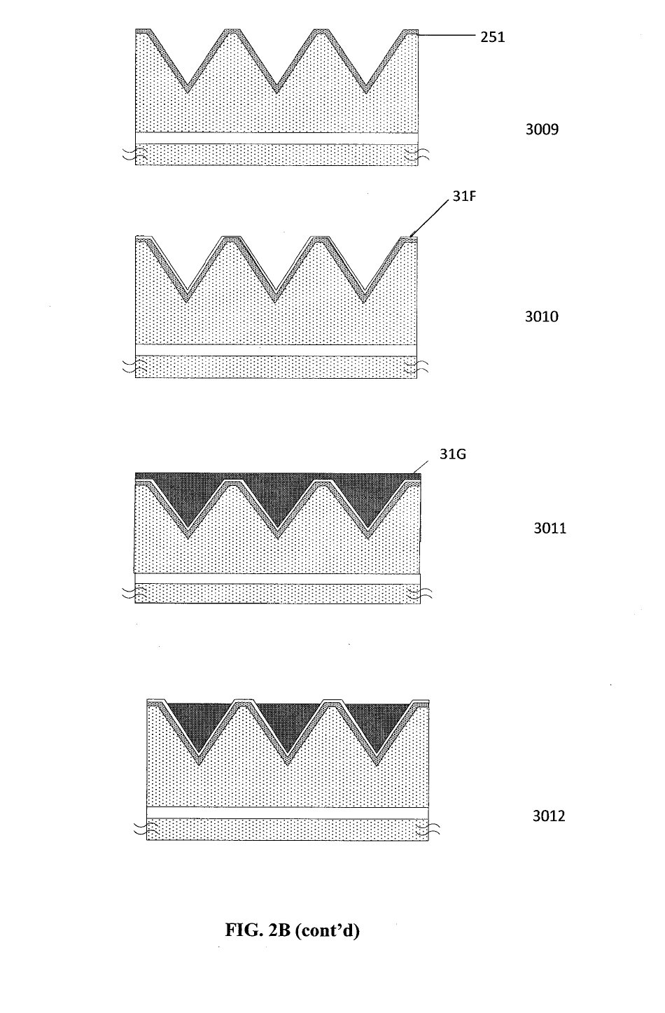

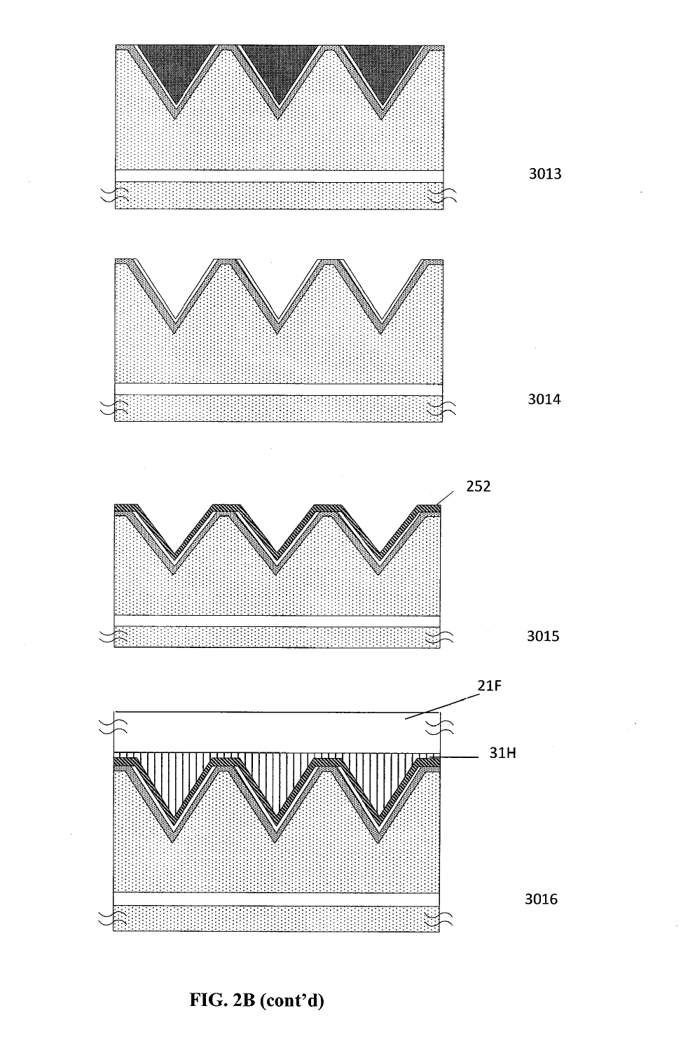

According to an embodiment, in stead of having a flat surface, the substrate 205 alternatively has a surface opposite the structures, the surface having recesses 270 (as shown in FIG. 2A). The surface opposite the structures 220 has the doped layer 251 conformally coated on the surface having recesses 270, the passivation layer 253 disposed conformally on some but not all areas of the doped layer 251 (e.g., on surfaces of the recesses 270 but not on surfaces 280 between the recesses), and the metal layer 252 disposed conformally on the doped layer 251 and the passivation layer 253 and forming an Ohmic contact with the doped layer 251, preferably at least at areas without the passivation layer 253. The recesses 270 can be filled and flattened with any suitable material. The doped layer 251 is electrically connected to each of the structures 220. The metal layer 252 is configured to reflect essentially all light passing through the substrate 205 back towards the structures 220. The passivation layer 253 can comprise oxide. Preferably, the doped layer 251 has higher doping level than the structures 220.

A method of making the surface having recesses 270 is described below and shown in FIG. 2B.

In step 3000, the substrate 205 is provided, which is a silicon-on-insulator (SOI) substrate having a doped silicon layer 21, a buried oxide layer 21B and a support layer 21C.

In step 3001, an oxide layer 31D is deposited onto the doped silicon layer 21 by a suitable method such as plasma-enhanced chemical vapor deposition (PECVD) or dry oxidation.

In step 3002, a resist layer 31E is applied to the oxide layer 31D, The resist layer 31E can be applied by spin coating. The resist layer 31E can be a photo resist or an e-beam resist.

In step 3003, lithography is performed. The resist layer 31E now has a pattern of openings in which the oxide layer 31D is exposed. The openings can be stripes, squares, rectangles, or a combination thereof. For example, the openings are 8 μm by 8 μm squares. The oxide layer 31D are exposed in the openings.

In step 3004, exposed portions of the oxide 31D is removed by a suitable method such as dry etch or wet etch. Now the doped silicon layer 21 is exposed in the openings of the resist layer 31E.

In step 3005, remainder of the resist layer 31E is lift off by a suitable solvent or ashed in a resist asher.

In step 3006, the doped silicon layer 21 is wet etched anisotropically by a suitable method to form recesses 270. The recesses 270 can be V-shaped trenches or inverted pyramids. For example, the surfaces of the V-shaped trenches or inverted pyramids are parallel to the {111} planes of the crystalline lattice of the doped silicon layer 21. KOH may be used for this wet etch.

In step 3007, remainder of the oxide 31D is removed by a suitable method such as dry etch or wet etch.

In step 3008, the doped layer 251 is formed by further doping a layer of the doped silicon layer 21 by ion implantation.

In step 3009, the substrate 205 is annealed, under an exemplary condition of 850° C. for 30 minutes.

In step 3010, an oxide layer 31F is deposited conformally (i.e., isotropically) on the doped layer 251 by a suitable technique such as evaporation, chemical vapor deposition or atomic layer deposition. The oxide layer 31F can be HfO₂, or SiO₂, or Al₂O₃.

In step 3011, a resist layer 31G is deposited on the oxide layer 31F such that the recesses 270 are filled and the oxide layer 31F is completely covered.

In step 3012, the resist layer 31G is etched by a suitable method such as plasma etch under oxygen atmosphere until the oxide layer 31F in areas between the recesses 270 is exposed. Alternatively, the resist layer 31G can be patterned by lithography to form a pattern of openings in the resist layer 31G in which the oxide layer 31F is exposed.

In step 3013, exposed portions of the oxide layer 31F is removed by a suitable method such as wet etch or dry etch.

In step 3014, remainder of the resist layer 31G is lift off by a suitable solvent or ashed in a resist asher.

In step 3015, the metal layer 252 is deposited by a suitable method such as evaporation or sputtering.

In step 3016, a wafer 31F is attached to the metal layer 252 to provide mechanical support. The wafer 31F can be attached by a heat conductive glue 31H. The wafer 31F can be any suitable wafer such as a ceramic plate, metal plate, glass plate, carbon fiber reinforced polymer (CFRP).

Steps 2011-2023 can be carried out next to finish the photovoltaic device.

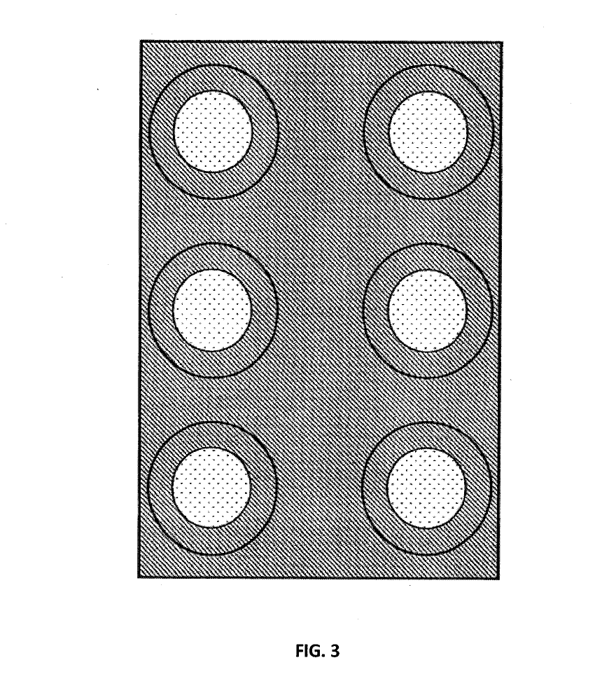

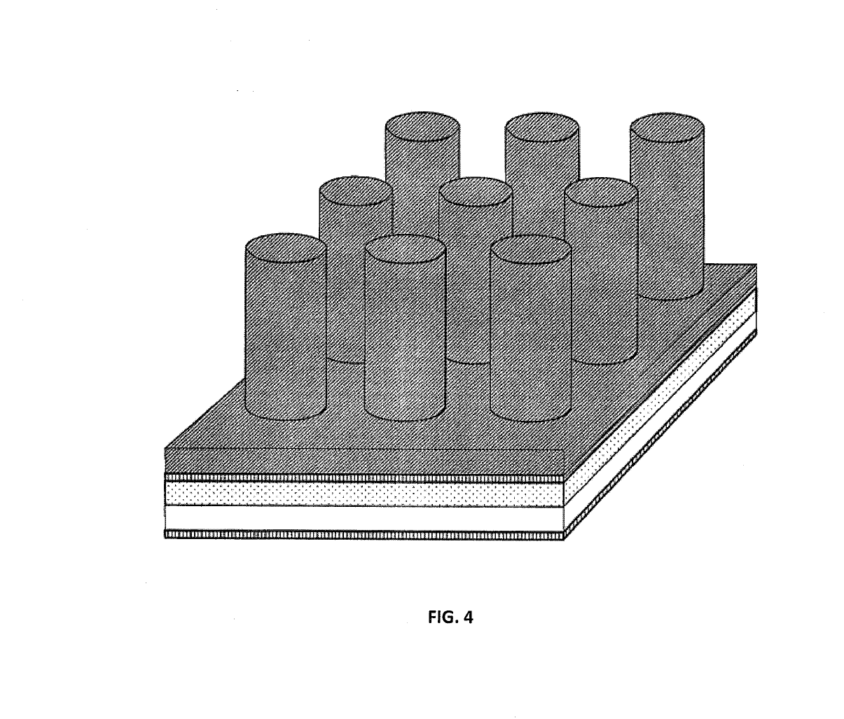

FIG. 3 shows an exemplary top cross sectional view of the photovoltaic device 100, 200 or 300. FIG. 4 shows an exemplary perspective view of the photovoltaic device 100, 200 or 300.

A method of converting light to electricity comprises: exposing the photovoltaic device 200 to light; selectively reflecting light to the structure 220 and selectively transmitting light to the substrate 205, using the wavelength-selective layer 232; absorbing the light and converting the light to electricity using the structure 220; drawing an electrical current from the photovoltaic device 200. As shown in FIGS. 1A and 1B, the electrical current can be drawn from the metal layer 252 and/or the wavelength-selective layer 232, in the photovoltaic device 200.

A photo detector according to an embodiment comprises the photovoltaic device 200, wherein the photo detector is configured to output an electrical signal when exposed to light.

A method of detecting light comprises: exposing the photovoltaic device 200 to light; measuring an electrical signal from the photovoltaic device 200. The electrical signal can be an electrical current, an electrical voltage, an electrical conductance and/or an electrical resistance. A bias voltage can be applied to the structures 220 in the photovoltaic device 200 when measuring the electrical signal.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A photovoltaic device operable to convert light to electricity, comprising a substrate, one or more structures essentially perpendicular to the substrate, and a wavelength-selective layer disposed on the substrate, wherein the structures comprise a crystalline semiconductor material.

2. The photovoltaic device of claim 1, wherein the structures comprise a doped semiconductor material.

3. The photovoltaic device of claim 1, wherein the single crystalline semiconductor material is selected from a group consisting of silicon, germanium, group III-V compound materials, group II-VI compound materials, and quaternary materials.

4. The photovoltaic device of claim 1, wherein the structures are cylinders or prisms with a cross-section selected from a group consisting of elliptical, circular, rectangular, and polygonal cross-sections, strips, or a mesh.

5. The photovoltaic device of claim 1, wherein the structures are pillars with diameters from 50 nm to 20 μm, heights from 1 μm to 100 μm, a center-to-center distance between two closest pillars of 300 nm to 15 μm.

6. The photovoltaic device of claim 1, wherein at least one region the one or more structures has a sidewall, a bottom wall, and a rounded, tapered or beveled inner edge between the sidewall and the bottom wall.

7. The photovoltaic device of claim 1, wherein the wavelength-selective layer is electrically conductive.

8. The photovoltaic device of claim 1, wherein the wavelength-selective layers are connected.

9. The photovoltaic device of claim 1, wherein the wavelength-selective layer is configured as an electrode of the photovoltaic device.

10. The photovoltaic device of claim 1, wherein wavelength-selective layer is operable to substantially transmit light of wavelengths above a threshold wavelength and substantially reflect light of wavelengths below the threshold wavelength.

11. The photovoltaic device of claim 9, wherein the threshold wavelength is a wavelength between 300 nm and 1100 nm.

12. The photovoltaic device of claim 1, wherein the wavelength-selective layer comprises a material selected from a group consisting of ZnO, Al, Au, Ag, Pd, Cr, Cu, Ti, and a combination thereof.

13. The photovoltaic device of claim 1, wherein the wavelength-selective layer has a thickness of 15 nm to 30 nm.

14. The photovoltaic device of claim 1, wherein the wavelength-selective layer comprises a dichroic mirror and an electrically conductive layer.

15. The photovoltaic device of claim 1, wherein the wavelength-selective layer comprises an alternating stack dielectric and electrically conducting layers.

16. The photovoltaic device of claim 9, wherein the wavelength-selective layer is configured to substantially reflect light of wavelengths below the threshold wavelength incident on the wavelength-selective layer to the structures so that the light is absorbed by the structures.

17. The photovoltaic device of claim 1, further comprising a junction layer, wherein:
the junction layer is a doped semiconductor; and
the junction layer is disposed on the sidewall, on the bottom wall under the wavelength-selective layer, and on a top surface of the structures.

18. The photovoltaic device of claim 17, wherein
the structures comprise a doped semiconductor and the structures and the junction layer have opposite conduction types.

19. The photovoltaic device of claim 17, wherein the junction layer has a thickness from 5 nm to 200 nm.

20. The photovoltaic device of claim 17, wherein the junction layer has a bandgap higher than a bandgap of the structures.

21. The photovoltaic device of claim 17, wherein the junction layer is amorphous silicon.

22. The photovoltaic device of claim 17, wherein the junction layer is effective to passivate surfaces of the structures.

23. The photovoltaic device of claim 17, wherein the junction layer and the structures form a p-n junction.

24. The photovoltaic device of claim 17, further comprising an intrinsic layer deposited between the junction layer and the structures, wherein the intrinsic layer is an intrinsic semiconductor.

25. The photovoltaic device of claim 24, wherein the intrinsic semiconductor is intrinsic amorphous silicon.

26. The photovoltaic device of claim 24, wherein the junction layer, intrinsic layer and the structures form a p-i-n junction.

27. The photovoltaic device of claim 17, further comprising, a cladding layer disposed over an entire exposed portion of the junction layer and the wavelength-selective layer.

28. The photovoltaic device of claim 27, wherein the cladding layer is substantially transparent to visible light with a transmittance of at least 50%; the cladding layer is made of an electrically conductive material; the cladding layer is a transparent conductive oxide; the cladding layer is a material selected from a group consisting of indium tin oxide, aluminum doped zinc oxide, zinc indium oxide, and zinc tin oxide; the cladding layer has a thickness from 10 nm to 500 nm; the cladding layer forms an Ohmic contact with the wavelength-selective layer; the cladding layer forms an Ohmic contact with the junction layer; and/or the cladding layer is configured as an electrode of the photovoltaic device.

29. The photovoltaic device of claim 27, further comprising a coupling layer disposed on the cladding layer.

30. The photovoltaic device of claim 29, wherein a refractive index of the structures is greater than a refractive index of the cladding layer; and the refractive index of the cladding layer is greater than refractive index of the coupling layer.

31. The photovoltaic device of claim 1, wherein the substrate has a surface opposite the structures, the surface having recesses.

32. The photovoltaic device of claim 31, further comprising a doped layer conformally coated on the surface, a passivation layer disposed conformally on some but not all areas of the doped layer, and a metal layer disposed conformally on the doped layer and the passivation layer and forming an Ohmic contact with the doped layer.

33. The photovoltaic device of claim 32, wherein the doped layer has the same conduction type from the structures;
the doped layer is electrically connected to at least some of the structures.

34. The photovoltaic device of claim 32, wherein the metal layer is configured to reflect essentially all light passing through the substrate back towards the structures.

35. The photovoltaic device of claim 1, wherein the substrate has a flat surface opposite the structures.

36. The photovoltaic device of claim 35, wherein the flat surface has a doped layer, a passivation layer deposited on the doped layer and a metal layer disposed on and forming an Ohmic contact with the doped layer.

37. The photovoltaic device of claim 35, wherein the passivation layer has a plurality of openings.

38. The photovoltaic device of claim 35, wherein the metal layer is configured to reflect essentially all light passing through the substrate back towards the structures.

39. A method of making the photovoltaic device of claim 1, comprising:
generating a pattern of openings in a resist layer using a lithography technique, wherein locations and shapes of the openings correspond to location and shapes of the structures;
forming the structures by etching the substrate;
depositing the wavelength-selective layer to the bottom wall.

40. The method of claim 39, further comprising ion implantation.

41. The method of claim 39, wherein the structures are formed by deep etch.

42. A method of making the photovoltaic device of claim 31, comprising: anisotropical wet etching.

43. A method of converting light to electricity comprising:
exposing a photovoltaic device to light, wherein the photovoltaic device comprises a substrate, one or more structures essentially perpendicular to the substrate, and a wavelength-selective layer disposed on the substrate, wherein the structures comprise a single crystalline semiconductor material;
selectively reflecting light to the structures and selectively transmitting light into the substrate, using the wavelength-selective layer;
absorbing the light and converting the light to electricity using the structures and the substrate;
drawing an electrical current from the photovoltaic device.

44. The method of claim 43, wherein the electrical current is drawn from the wavelength-selective layer.

45. A photo detector comprising the photovoltaic device of claim 1, wherein the photo detector is configured to output an electrical signal when exposed to light.

46. A method of detecting light comprises:
exposing the photovoltaic device of claim 1 to light;
measuring an electrical signal from the photovoltaic device.

47. The method of claim 46, wherein the electrical signal is an electrical current, an electrical voltage, an electrical conductance and/or an electrical resistance.

48. The method of claim 46, wherein a bias voltage is applied to the structures in the photovoltaic device.

49. The photovoltaic device of claim 1, wherein the crystalline semiconductor material is a single-crystal.
